(19) United States
(12) Patent Application Publication
(10) Pub. No.: US 2024/0258215 A1
(43) Pub. Date: Aug. 1, 2024

(54) WIRE BONDED SEMICONDUCTOR DEVICE PACKAGE

(71) Applicant: TEXAS INSTRUMENTS INCORPORATED, Dallas, TX (US)

(72) Inventors: Mei Jiao, Chengdu (CN); Huo Yun Duan, Chengdu (CN); Zi Qi Wang, Chengdu (CN); Tiange Xie, Chengdu (CN)

(21) Appl. No.: 18/162,079

(22) Filed: Jan. 31, 2023

(51) Int. Cl. H01L 23/495; H01L 23/00; H01L 23/31

(52) U.S. Cl. CPC H01L 23/49575; H01L 23/3107; H01L 24/32; H01L 24/48; H01L 24/73; H01L 2224/32245; H01L 2224/48091; H01L 2224/48247; H01L 2224/48463; H01L 2224/73265; H01L 2924/181

(57) ABSTRACT

An example apparatus includes: a metal leadframe including a die pad in a central portion and leads spaced from the die pad. The leads include: an interior end spaced from the die pad and having a full thickness of the metal leadframe; a central portion connected to the interior end and extending away from the die pad having a partial thickness less than the full thickness; and an exterior end having the full thickness extending from the central portion. A semiconductor die is mounted to the die pad by die attach material. Wire bonds couple bond pads of the semiconductor die to the interior ends of the leads. Mold compound covers the semiconductor die, the die pad, the wire bonds, the interior ends of the leads, the central portion of the leads, and portions of the exterior ends of the leads to form a semiconductor device package.

### TECHNICAL FIELD

This disclosure relates generally to semiconductor device packages, and more particularly to semiconductor device packages including a semiconductor die mounted to a leadframe in a molded package.

### BACKGROUND

Leaded and no-lead semiconductor device packages are used to provide semiconductor devices for mounting to system boards. Leadless semiconductor device packages including small outline no-lead (SON) and quad flat no-lead (QFN) type packages are increasingly used. No-lead or leadless packages have external terminals that are formed within the area of the semiconductor device package body, and which are for surface mounting to a board. Because the package terminals are exposed lead portions that are placed beneath the package body, the total board area needed for the no-lead semiconductor device package is reduced when compared to leaded package types, which use more board area for mounting.

No-lead packages can be formed using a leadframe, and when the package includes a leadframe the package can be referred to as a “leadless leadframe semiconductor device package.” The no-lead package can be formed using a face up mounted semiconductor die that is electrically connected to leads of the leadframe by bond wires or ribbon bonds. Bond wires can be formed in a wire bonding process.

The leads in some leadless leadframe semiconductor device packages can be described as having “cantilever” shapes. Cantilever leads have different thicknesses in different portions. An exterior end of the lead, the end farthest from the semiconductor die, may be a full leadframe thickness. A portion of the exterior end of the lead also forms an external terminal for the no-lead package. An interior end of the lead, which ends proximate to a die pad for mounting the semiconductor die and is therefore positioned away from the exterior end, may be a partial thickness of the total leadframe thickness. Because the interior parts of the leads are thinner than the exterior ends of the leads, these leads can be described as having a “cantilever” shape. By forming a cantilever shape, with the interior end of the lead being the thinner portion, the adhesion of mold compound or resin that forms the package body is increased. The exposed portion of the exterior end of the lead forms a terminal for the semiconductor device package that is made large enough for a reliable surface mount solder joint to a board, while the remaining portion of the cantilever lead extending towards the interior end is thinner and is covered by the mold compound on the bottom of the semiconductor device package.

In a wire bonded semiconductor device package, whether leaded or no-lead types, the semiconductor die has bond pads that are used to form electrical connections to the leads using bond wires. Wire bonding is a well understood process long used in the semiconductor industry, and has the advantages of allowing for flexible semiconductor die sizes and flexible bond pad placement on the semiconductor dies for use in packaging processes. When a wire bonding tool makes a stitch bond to the surface of the interior end of a cantilever lead, the wire bonding tool applies mechanical pressure to form the stitch bond to a surface of the lead and pushes against the lead. If the lead is not otherwise supported during the wire bonding process, the cantilever lead can become deflected or misaligned, which can result in a defective finished device. Example defects include leads where the exposed surface is deflected so that the mold compound formed in a subsequent molding process covers part or all of the lead that should be exposed to form a terminal, a “mold flash” defect. Other defects include misalignment of the leads in the finished package.

In one approach a custom wire bonding tool is used with additional custom heater blocks designed for a specific semiconductor device die, the custom blocks are placed beneath the interior end of each of the leads before wire bonding, so that the cantilever lead is supported for the wire bonding process. However, if the interior end of the cantilever lead is misaligned to the heater blocks, both of which are quite small, the lead may still deflect during wire bonding, resulting in mold flash defects during subsequent molding processes. The external end of the lead may be deflected or deformed, and when molding is performed, may be partially or wholly covered by mold compound, making surface mount solder joints unreliable.

An effective, reliable, and cost efficient method is needed to make semiconductor device packages with wire bonding.

### SUMMARY

An example apparatus includes a metal leadframe including: a die pad in a central portion of the metal leadframe and having a thickness that is the same as a full thickness of the metal leadframe; and leads spaced from the die pad. The leads include: an interior end spaced from the die pad by an opening in the metal leadframe and having the full thickness; a central portion connected to the interior end and extending away from the die pad having a partial thickness that is less than the full thickness; and an exterior end having the full thickness extending from the central portion and away from the die pad, the exterior end having a board side surface. A semiconductor die is mounted to the die pad by die attach material and having bond pads on a device side surface facing away from the die pad. Wire bonds couple the bond pads of the semiconductor die to the interior ends of leads of the metal leadframe. Mold compound covers the semiconductor die, the die pad, the wire bonds, the interior ends of the leads, the central portion of the leads, and portions of the exterior ends of the leads to form a semiconductor device package. The board side surface of the exterior ends is exposed from the mold compound and forms terminals for the semiconductor device package.

In another described example, a method includes: placing a partially etched leadframe on a tape with a board side of the leadframe facing the tape, the partially etched leadframe having leads with full thickness interior ends connected by a partial thickness center portion to full thickness exterior ends, where the partial thickness is a thickness less than the full thickness; forming die attach material on a die pad on the device side surface of the partially etched leadframe, the interior ends of the leads proximal to the die pad; placing a semiconductor die on the die pad using the die attach material with bond pads of the semiconductor die facing away from the die; forming wire bond connections between the bond pads and the interior ends of the leads of the leadframe; and covering the semiconductor die, the die pad, the bond wires, the interior ends of the leads, the center portions of the leads, and portions of the exterior ends of the leads with mold compound to form a semiconductor device package.

### BRIEF DESCRIPTION OF THE DRAWINGS

FIGS. 1A-1B illustrate, in a projection view and a close up projection view, respectively, semiconductor dies on a semiconductor wafer, and an individual semiconductor die from the semiconductor wafer for use with the arrangements.

FIG. 2 illustrates, in a projection view, a no-leads semiconductor device package which can be used in an arrangement.

FIGS. 3A-3C illustrate, in a board side view, a cross-section, and a detailed cross section, respectively, features of a semiconductor device package of an example arrangement.

FIGS. 4A-4E illustrate, in a series of views, selected steps for forming semiconductor device packages of the arrangements.

FIGS. 5A and 5B illustrate, in a board side view and a close up view, details of a leadframe and of a lead, respectively, for use in an arrangement.

FIG. 6 illustrates, in a flow diagram, a method for forming a semiconductor device package of an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements, conductors, or wires are coupled. In an example arrangement, a sensor receives a magnetic field from a conductor carrying current and is coupled to the conductor, even though the sensor is isolated from the conductor, and no current flows between the sensor and the conductor.

The term “semiconductor die” is used herein. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device. The semiconductor die can include a power transistor, an analog device, or a sensor.

The term “semiconductor device package” is used herein. A semiconductor device package has at least one semiconductor die electrically coupled to terminals, and has a package body that protects and covers the semiconductor die. The semiconductor device package can include additional elements. Passive components such as sensors, antennas, capacitors, coils, inductors, and resistors can be included. In some arrangements, multiple semiconductor dies can be packaged together. Circuitry that combines functions such as a sensor and an amplifier semiconductor die and a logic semiconductor die (such as a controller die or digital filter) can be packaged together to from a single semiconductor device package. The semiconductor die is/are mounted to a package substrate that provides conductive leads. A portion of the conductive leads form external leads for the packaged device. In wire bonded semiconductor device packages used in the arrangements, bond wires or ribbon bonds couple conductive leads of a package substrate to bond pads on the semiconductor die. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the external terminals for the semiconductor device package.

The term “package substrate” is used herein. A package substrate is a substrate arranged to receive a semiconductor die and to support the semiconductor die in a completed semiconductor device package. Package substrates can include conductive leadframes, which can be formed from copper, aluminum, stainless steel, steel and alloys such as Alloy 42 and copper alloys. Conductive leads are positioned for coupling to bond pads on the semiconductor die. In an example arrangement, the electrical connections from the bond pads to the leads are formed using wire bonds. The leadframes can be provided in strips, grids or arrays. The conductive leadframes can be provided as a panel or grid with strips or arrays of unit leadframe portions in rows and columns. Semiconductor dies can be placed on respective unit device leadframe portions within the strips or arrays. The leadframe leads may have plated portions in areas designated for wire bond connections to the semiconductor die, for example silver plating can be used.

In packaging semiconductor devices, mold compound may be used to partially cover a package substrate, to cover components, to cover a semiconductor die or multiple semiconductor dies, and to cover the electrical connections from the semiconductor die or dies to the package substrate. This molding process can be referred to as “encapsulation”, although some portions of the package substrates are not covered in the mold compound during encapsulation. For example, in the arrangements, portions of the leads are left exposed from the mold compound. Encapsulation is often a compressive molding process, where thermoset mold compound such as resin epoxy can be used. Mold compound used in electronic packaging is sometimes referred to as “EMC” or “epoxy mold compound.” A room temperature solid or powder mold compound can be heated to a liquid state, and then transfer molding can be performed by pressing the liquid mold compound into a mold through runners or channels. Unit molds shaped to surround an individual device may be used, or block molding may be used. The molding process forms multiple packages simultaneously for several devices. The devices to be molded can be provided in an array or matrix of several, hundreds or even thousands of devices in rows and columns on a leadframe strip. The semiconductor devices that are then molded at the same time to increase throughput. After the mold process forms the molded semiconductor device packages, the individual units are separated from one another by cutting through the mold compound and the package substrate between the devices using a saw, a laser or another cutting tool.

The term “scribe lane” is used herein. A scribe lane is a portion of semiconductor wafer between semiconductor dies. Sometimes the term “scribe street” is used. Once semiconductor processing is completed and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area defined between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are normal to each other and the saw will traverse the molded electronic devices in two different directions to cut apart the packaged electronic devices from one another in the array.

In the arrangements, a semiconductor device package includes a semiconductor die mounted to a leadframe having wire bond connections between the semiconductor die and leads of the leadframe. The leadframe has a die pad in a central portion for mounting the semiconductor die. The die pad has a full thickness, that is the total thickness of the leadframe. The leadframe has leads with interior ends proximate to but spaced from the die pad. The leadframe leads have exterior ends that form terminals for the semiconductor device package. The interior ends of the leads have a full thickness portion with a bottom surface that will support the interior end of the leads during a wire bonding process. A central portion of the leads is a partial thickness that is less than the full thickness. The exterior end of the leads are connected to the interior ends by the central portion of the leads. The exterior end of the leads have the full thickness and a portion of the exterior end forms a terminal for surface mounting the semiconductor device package. A semiconductor die is mounted to the die pad, and bond wire connections are formed between bond pads on a device side surface of the semiconductor die and the interior leads of the leadframe. By use of the full thickness on the interior ends of the leads of the leadframe in the arrangements, defects caused by lead deflection or lead misalignment that occurred during wire bonding using prior approaches formed without the arrangements are eliminated. The leadframe leads of the arrangements can be formed using a partial etch or stamping operation when the leadframe is manufactured, without the need for additional materials or parts. The materials used in the arrangements and the processing steps used for forming the arrangements do not require modifications to the existing packaging processes, semiconductor dies, or wire bonding tools, so that use of the arrangements results in increased reliability at low costs.

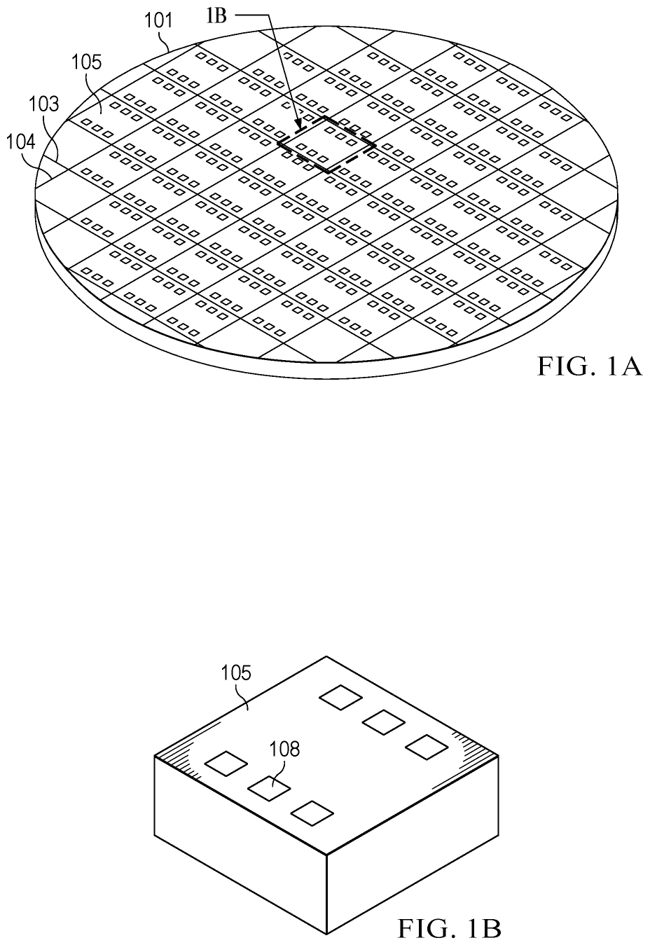

FIGS. 1A and 1B illustrate in projection views a semiconductor wafer 101 having semiconductor devices formed on it (FIG. 1A), and an individual semiconductor die 105 from the wafer for wire bonding and face up mounting (FIG. 1B), respectively. In FIG. 1A, a semiconductor wafer 101 is shown with an array of semiconductor dies 105 formed in rows and columns on a device side surface. The semiconductor dies 105 can be formed using processes typically used in a semiconductor manufacturing facility, including ion implantation, substrate doping, thermal anneals, oxidation, dielectric and metal deposition, sputter, photolithography, pattern, etch, strip, chemical mechanical polishing (CMP), electroplating, and other processes for making semiconductor devices on wafers. Scribe lanes 103 and 104, which are perpendicular to one another and which run in parallel groups across the wafer 101, separate the rows and columns of the completed semiconductor dies 105, and provide areas for dicing the semiconductor wafer 101 so as to separate the semiconductor dies 105 from one another.

FIG. 1B illustrates a single semiconductor die 105 after singulation from the semiconductor wafer 101, with bond pads 108, which are conductive pads that are electrically coupled to devices (not shown) formed on a device side surface of the semiconductor die 105. The bond pads 108 are positioned for connection to leads of a semiconductor device package.

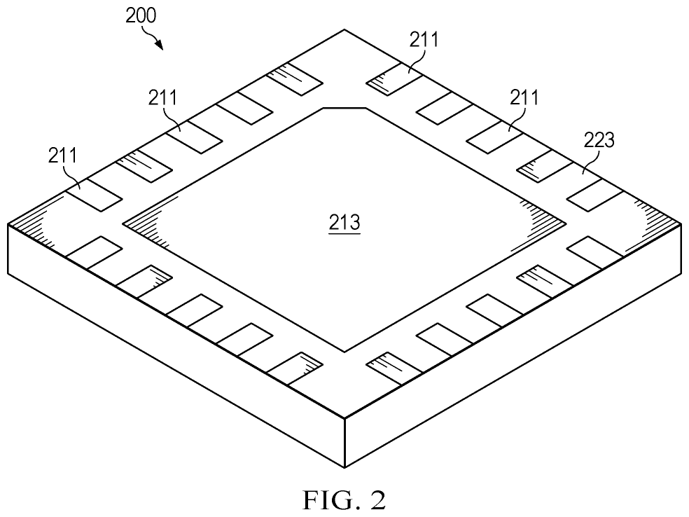

FIG. 2 illustrates in a projection view from a board side a quad flat no-lead (QFN) semiconductor device package 200 that is useful with the arrangements. In the illustrated example, the semiconductor device package has sixteen terminals 211 for surface mounting to a board using solder. Die pad 213 is exposed from the mold compound 223 that forms the package body, and can be used as a thermal path to remove excess heat from a semiconductor die (not visible) mounted within the semiconductor device package 200. Other no-lead semiconductor packages can be used with the arrangements such as small outline no-lead (SON) package. Alternatively, leaded packages such as small outline integrated circuit (SOIC) or dual in-line package (DIP) semiconductor packages can be used with the arrangements. To reduce size and volume of systems formed using semiconductor devices, reduction in semiconductor package sizes are continuously desired. No-lead semiconductor device packages take less board area for mounting and are increasingly used. While the illustrated examples are for no-lead packages, the arrangements can also be used with leadframes for leaded semiconductor device packages.

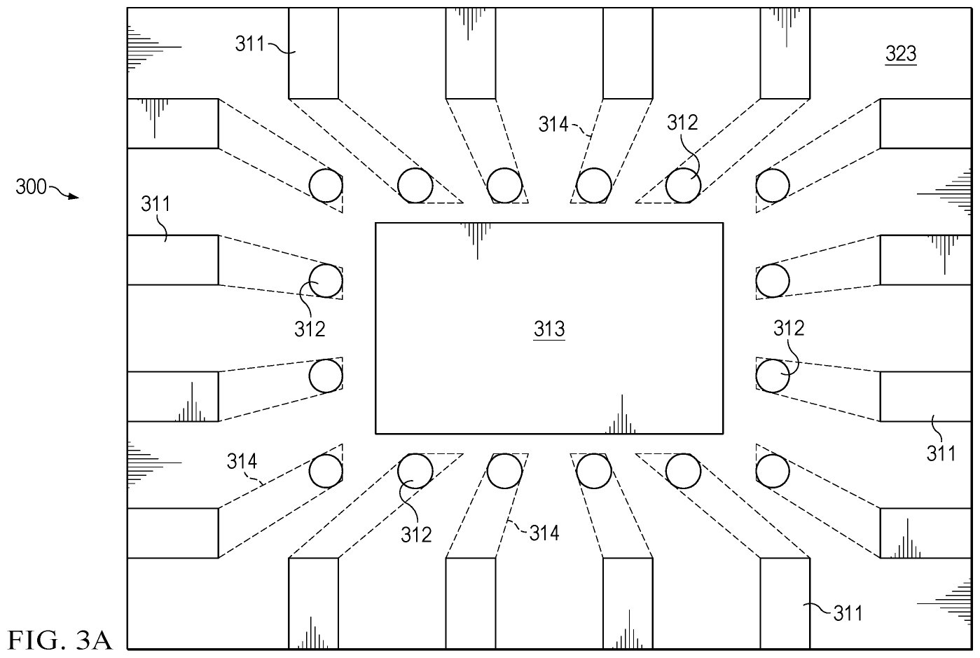

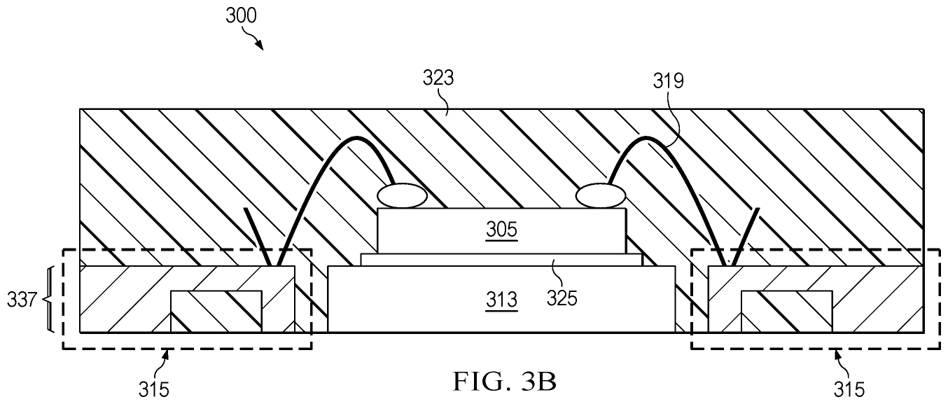

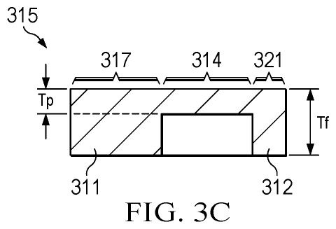

FIG. 3A illustrates, in a bottom view of a board side surface, a semiconductor device package 300 for use with an example arrangement. In FIG. 3A an example QFN package is shown. Terminals 311, which are configured to be surface mounted (similar to terminals 211 in FIG. 2), are portions of leadframe leads (not shown in FIG. 3A, see leads 315 in FIG. 3B) that are exposed from mold compound 323. A die pad 313 is also a part of the leadframe and has a full thickness, and so the board side surface of the die pad 313 is exposed from the mold compound 323.

FIG. 3B illustrates the semiconductor device package 300 of FIG. 3A in a cross section. In FIG. 3B, a semiconductor die 305 is shown mounted by a die attach material 325 to a device side surface of die pad 313, which is a central portion of a leadframe 337. The leadframe 337 has leads 315 which have a full thickness at an interior end that is proximal to and spaced from the die pad 313. Leadframe 337 can be of copper, plated copper, Alloy 42, stainless steel or other conductive metals and alloys. The leadframe 337 can be partially etched or stamped from a sheet material, for example. In a partial etching process, areas of the leadframe can be completely etched to form spaces or holes, or the leadframe can be selectively partially etched from one side or from the opposite side to form areas of varying thicknesses. A sheet material such as a copper sheet can be used as a starting material and patterned using full etch and partial etch processes. Stamping can be used to pattern leadframes. Areas of a copper leadframe that are to be soldered can be plated or tinned to prevent corrosion and increase solderability. Areas for wire bond connections can be plated to increase bond strength and also to reduce or eliminate diffusion and oxidation or tarnish. Platings can include gold, palladium, nickel, silver, tin, and combination layers such as electroless nickel immersion gold (ENIG) and electroless nickel, electroless palladium and immersion gold (ENEPIG). Silver spot plating can be used.

The semiconductor die 305 is electrically connected to leads 315 of the leadframe 337 by bond wires 319. Bond wires 319 are conductive wires that are connected from bond pads on the semiconductor die 305 to the leads 315 in a wire bonding tool. The wire bond connections can be made using bond wires of gold, copper, palladium coated copper, aluminum or silver. In an example, palladium coated copper bond wire of about 20 microns in diameter is used. Other diameters of bond wire can be used, depending on materials chosen for the bond wire and desired electrical characteristics of the bond wire. Useful examples include 20 microns, 25.4 microns, 33 microns, and 50 microns of diameter for palladium coated copper and copper bond wires.

In an example wire bonding operation, a wire bond begins with an exposed end of a bond wire extending from an opening in a capillary of the wire bonding tool. The capillary has a bottom surface configured to be used to press the bond wire against a bond pad or lead during bonding. A heat source such as a flame or electric spark is used to melt the exposed end of the bond wire to form a ball on the end of the bond wire. The ball is then mechanically pressed onto a bond pad using the surface of the capillary to apply mechanical pressure, and in many examples, ultrasonic energy is applied during ball bonding to create a metal to metal bond between the ball formed on the end of the bond wire and the bond pad. The semiconductor device and the leadframe may be heated to further improve bonding. The bond pads can be formed of metallization material used in semiconductor processes including aluminum and copper bond pads and alloys of these. The wire bonding tool may include heat blocks to support and heat the semiconductor die and the leadframe leads to provide thermosonic wire bonding, using heat, pressure, ultrasonic energy, in combination to form the bonds.

After the ball is bonded to a bond pad, the capillary of the wire bonding tool moves over a portion of a conductive lead and a stitch bond can be formed on the surface of the lead. While the capillary is moving, the bond wire is allowed to extend from the ball bond on the bond pad through the capillary opening and arcs above the leadframe and the semiconductor die, and then the bond wire is pulled down to a leadframe lead. The capillary then makes a mechanical stitch bond to the lead by pressing the bond wire against the lead and again using ultrasonic energy. As the capillary moves away from the stitch bond on the lead, the bond wire is then cut at a short distance from the lead. In the arrangements, as is further described below, the interior ends of the leadframe leads are formed of a full thickness of the leadframe. This feature of the arrangements improves the stitch bond and the bonding process by preventing deflection of the lead during wire bonding. Defects that are observed using prior approaches due to misalignment of the leads, and unwanted movement of the leads during wire bonding, are eliminated by use of the arrangements.

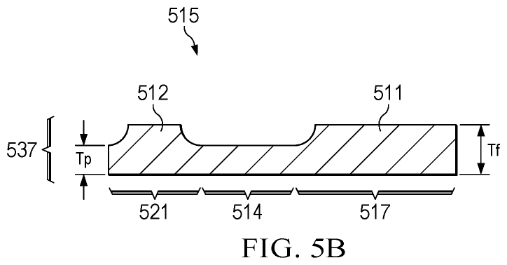

FIG. 3C is a cross sectional view of a single lead 315 to illustrate further details. Lead 315 has a full thickness labeled “Tf” at the interior end 321, a partial thickness labeled “Tp” in the central portion 314 that extends from the interior end away from the die pad of the semiconductor package (see die pad 313 in FIG. 3B), and a full thickness (again thickness Tf) for the exterior end 317 which is positioned away from the die pad 313. The partial thickness Tp can be, in one example, about one-half of the full thickness Tf. Other partial thicknesses can be used, such as less than one-half of the full thickness Tf. Leadframe thicknesses useful with the arrangements include leadframes from 0.1-0.25 millimeters for the full thickness. In an particular example a leadframe of 0.127 millimeters was used. The lead 315 has the central portion 314 with the partial thickness Tp which can be formed by an etch or stamping operation. In an example process, a strip, grid or array of unit leadframes is formed from a sheet material such as a copper sheet material. The strip or grid can have tens, hundreds or more unit leadframes patterned on it, the strip or grid or unit leadframes can be used in a semiconductor device packaging process to simultaneously produce many semiconductor device packages in a single run, increasing throughput and thereby reducing costs for each one. While the example lead 315 is shown with a rectangular cross section, particularly for the intersections between the partial thickness of the central portion 314 and the full thickness of the exterior end 317 and the interior end 321, when an etching process is used to form the leads, the side of the central portion 314 facing the board side surface (the bottom of the lead 315 as oriented in FIG. 3C) may have a curved surface due to the profile created in a metal etch process. (See the cross section of lead 515 in FIG. 5B, for example.) The bottom surface of lead 315, which is the board side surface, has an exterior terminal portion 311, and an interior portion 312, that will be exposed from the mold compound in the semiconductor device package (see 311, 312 in FIG. 3A).

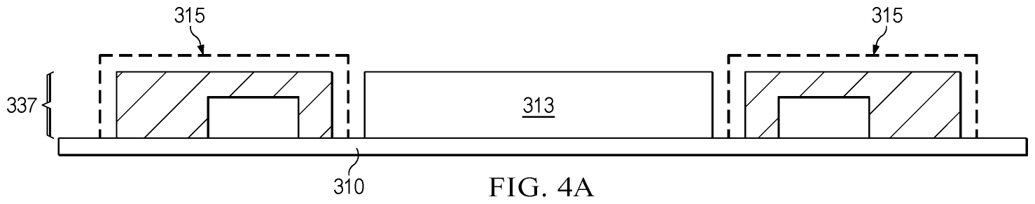

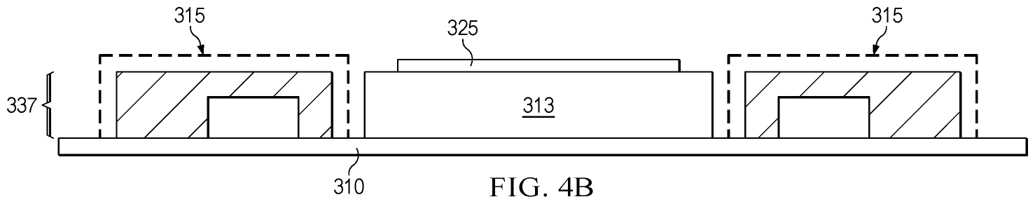

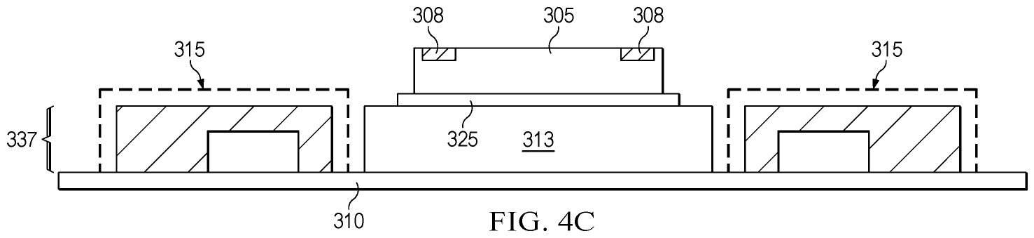

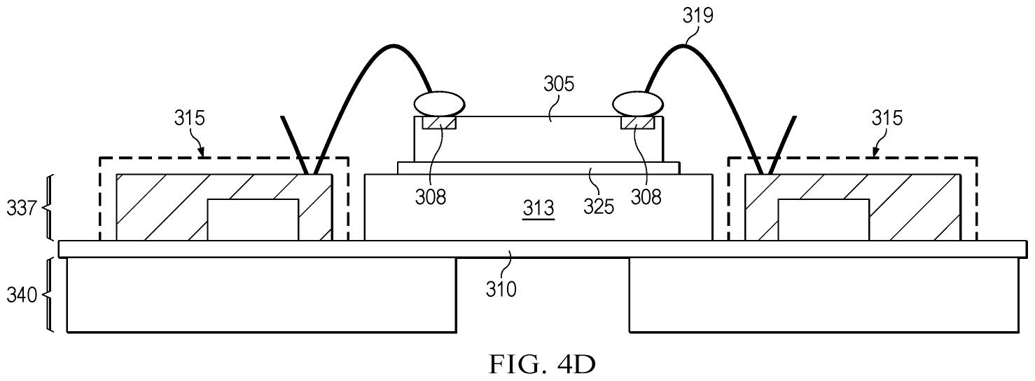

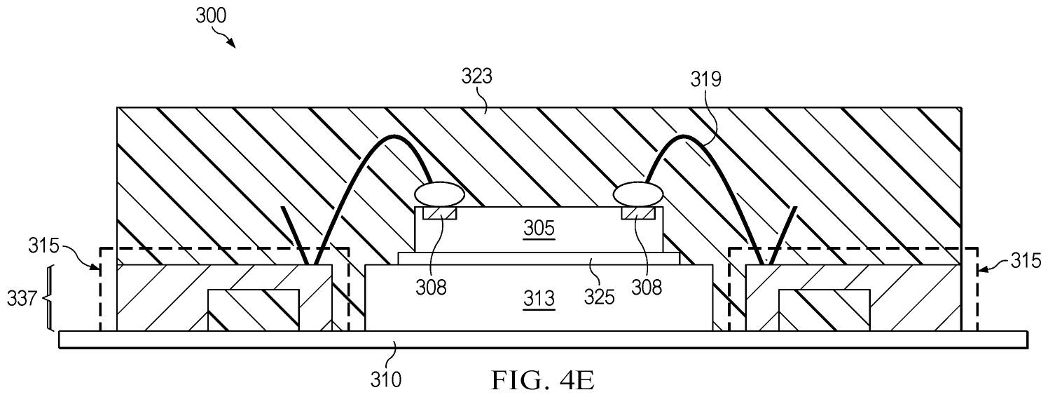

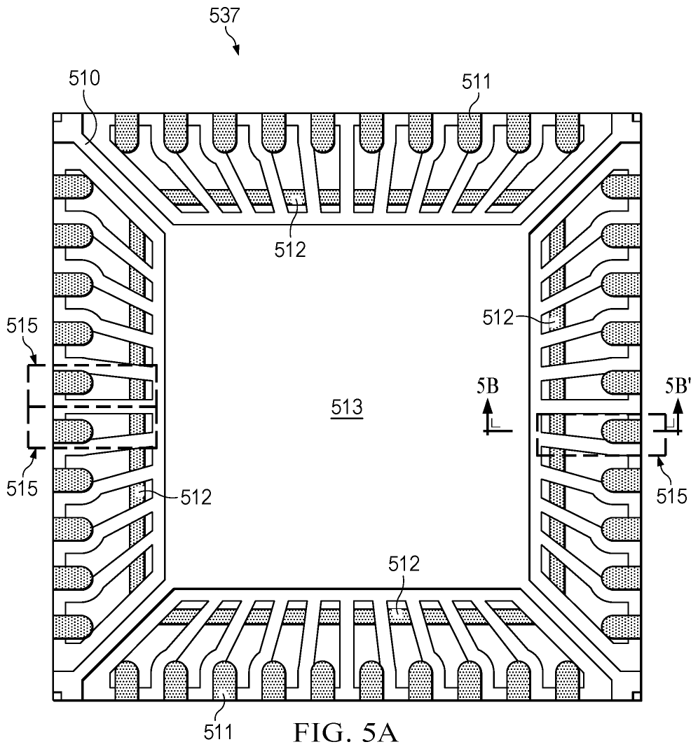

FIGS. 4A-4E illustrate, in a series of views, selected steps for forming a packaged semiconductor device in an example arrangement.

FIG. 4A illustrates, in a cross sectional view, a leadframe 337 mounted on a tape 310 for use in the packaging process. The leadframe 337 can be formed by a stamping or etching process of a sheet material for the leadframe, and may be of copper, copper alloy, Alloy 42, stainless steel, steel, or another conductor. The leadframe 337 has a die pad 313 and leads 315 spaced from the die pad 313. During processing, the leads can be temporarily connected for support during processing by tie bars or dam bars (not shown) that are outside the cross sectional view of FIG. 4A.

Tape 310 can be a removable adhesive film such as a QFN tape product available from INNOX Advanced Materials Company, Limited, of South Korea. In an example process tape 310 can be a polyimide film with an adhesive and a release film cover. A taping machine can be used to apply the tape to the board side surface of the leadframes in an automated process. The tape 310 can include a peelable adhesive so that when the tape 310 is removed after molding, the adhesive is easily removed or is removed along with the tape. Because heat is applied during processes such as molding, the tape is preferably heat resistant. Other removeable films can be used such as UV peelable films. The leadframe 337 and tape 310 can be combined and provided as a supplied component to the packaging process, and this part of the processing can be performed independently of the semiconductor fabrication processes, and at various locations, and asynchronously with respect to the rest of the processes.

FIG. 4B illustrates the leadframe 337 of FIG. 4A after additional processing. To prepare for die mounting steps to follow, a die attach material 325 is first formed on the device side surface of die pad 313 of the leadframe 337. The die attach material 325 can be die attach epoxy. The die attach epoxy can be dispensed by a needle dispenser as a liquid or gel, and alternatively the die attach epoxy can be dispensed using an ink jet or drop on demand system, or by use of a stencil. The die attach material 325 can be a die attach tape or film. Because the die pad 313 has a board side surface that will be exposed from the mold compound in the completed semiconductor device package (see die pad 313 in semiconductor device package 300 in FIG. 3B), the die pad 313 provides a convenient thermal path for removing heat from a semiconductor die. Accordingly, the die attach material 325 can be thermally conductive. In addition, the die pad can be coupled to a ground or bias potential. In some applications the die attach material 325 can be electrically conductive. Alternatively, in other applications, the die attach material can be electrically insulating when the semiconductor die to be mounted to the die pad is to be electrically isolated from the die pad 313.

FIG. 4C illustrates in another cross sectional view the leadframe 337 of FIG. 4B after a die mounting operation. In an example process, a pick and place tool or other die handling tools can be used to place semiconductor die 305 on the die attach material 325 to mount the semiconductor die 305 to the die pad 313. The semiconductor die 305 is shown with bond pads 308, which can be aluminum, copper, alloys or plated metals, exposed and facing away from the die pad 313, in preparation for wire bonding. Leads 315 are spaced from the die pad 313 and from semiconductor die 305.

FIG. 4D illustrates in another cross section the semiconductor die 305 and leadframe 337 of FIG. 4C after additional processing. As shown in FIG. 4D, wire bonds 319 have been formed between bond pads 308 and the upper surface of the leads 315. In an example wire bonding process, a wire bonding tool has a capillary with a surface for making ball bonds and stitch bonds on surfaces, and has a central opening. The capillary can be made of a ceramic, a metal or other hard material. An end of a bond wire is allowed to protrude through the opening to a short distance. A flame or electronic spark is used to heat the end of the bond wire to form a ball. The wire bonder moves the capillary over a bond pad and using mechanical pressure forces the ball against the bond pad, often along with ultrasonic energy and heat, and forms a ball bond to the bond pad. The bond wire remains attached to the ball bond. As the capillary is moved above the leadframe, the bond wire extends through the opening in the capillary and forms an arc or curved shape. The capillary aligns with a predetermined bond spot over a lead. The capillary then presses the wire against the lead and forms a stitch bond on the lead. As the capillary moves from the stitch bond, the bond wire is cut and the cut end extending from the capillary is used to form the next ball is a repetitive process. The wire bond may have a short tail extending from the stitch bond.

In the arrangements, the stitch bonds are formed on the interior end of the leads 315, and this interior end of the lead is a full thickness portion of the leadframe 337. In this manner, the stitch bonding operation is performed on a portion of the lead that is supported by a heating block 340, which can be a heated block of metal or other hard material and can include a central vacuum to hold the tape 310. The tape 310 and the heating block 340 support the lead 315 and leadframe 337 so that during wire bonding, the lead 315 is not deflected or moved. Use of the full thickness of the leadframe at the interior end of the leads in the arrangements prevents defects due to misalignment or deflection of the leads that occurred in bonding operations performed without the arrangements.

FIG. 4E illustrates, in a further cross section, a semiconductor device package 300 formed by additional processing on the semiconductor die 305 of FIG. 4D. In FIG. 4E, a mold compound 323 has been formed over the semiconductor die 305, the bond wires 319, and portions of the leadframe 337. Portions of the leads 315 such as the board side surfaces of the interior ends of the leads, and of the exterior ends of the leads, where the full thickness is used, are exposed from the mold compound (see 311, 312 in FIG. 3A, for example). The exposed surfaces of the exterior ends are for surface mounting to a system board. The board side surface of the die pad 313 is also exposed from the mold compound. The mold compound can be an epoxy mold compound (EMC), an epoxy, a resin, or a plastic. In an example molding process, a transfer mold is used. Solid thermoset resin, which can be a pellet or a powder, is heated to a liquid state. A ram forces the liquid mold compound through runners into molds in a mold chase where the leadframes are positioned holding the semiconductor dies, the bond wires, and the leads in position while the mold compound flows into the molds. The mold compound is then allowed to cure and cools to a solid package around the semiconductor dies and the leadframes. As shown in FIG. 4E, after the mold step the tape 310 remains in place. To complete the semiconductor device package as shown in FIG. 3A-3B the tape 310 is removed from the board side surface of the semiconductor device packages. A singulation step may be performed to cut unit devices from a leadframe strip or array and singulate the semiconductor device packages one from another.

FIG. 5A is a bottom view of a leadframe 537 that is useful with the arrangements, looking from a board side surface. In FIG. 5A, leadframe 537 has a die pad 513 in a central portion. Tie straps 510 which extend to the corners of the die pad 513 provide support. Leads 515, which are similar to lead 315 in FIG. 3C, are shown spaced from and surrounding the die pad 513. The leads have a surface 512 on an interior end proximate to the die pad 513, and a surface 511 on an exterior end away from the die pad 513, and these are full thickness portions of the leads 515. Surfaces 511 and 512 which face the viewer in FIG. 5A will be exposed from the mold compound when the leadframe 537 is used in a completed package (see 311, and 312, in the bottom view of package 300 in FIG. 3A, for example).

FIG. 5B is a close up cross section taken along the line 5B-5B′ in FIG. 5 is shown to further illustrate details of an individual leadframe lead. The lead 515 in FIG. 5B is oriented with the board side facing up, as in FIG. 5A. The example lead 515 has an interior end 521 and an exterior end 517 that are of the full thickness Tf of the leadframe 537. A central portion 514 is connected to the interior end 521 and extends away from the die pad (see 513 in FIG. 5A) to the exterior end 517, central portion 514 is of a partial thickness Tp that is less than the full thickness Tf of the leadframe 537. The leads of the leadframes used in the arrangements can be formed in a partial etch process by etching metal sheets the leadframe is made from starting at the board side, which forms the curved surface of the central portion 514 shown in FIG. 5B. Alternatively the leadframes can be formed in a stamping operation. The interior end 521 of lead 515 has board side surface 512 that will be exposed from the mold compound when the lead is covered in a molding step (see FIG. 3A, for example, where the surfaces 312 are shown in a plan view of a similar arrangement). The exterior end 517 has a board side surface 511 that will be exposed from the mold compound and which will form a surface mount terminal for the packaged semiconductor device (see surface 312 in the plan view of FIG. 3A where a similar leadframe and the corresponding package are shown).

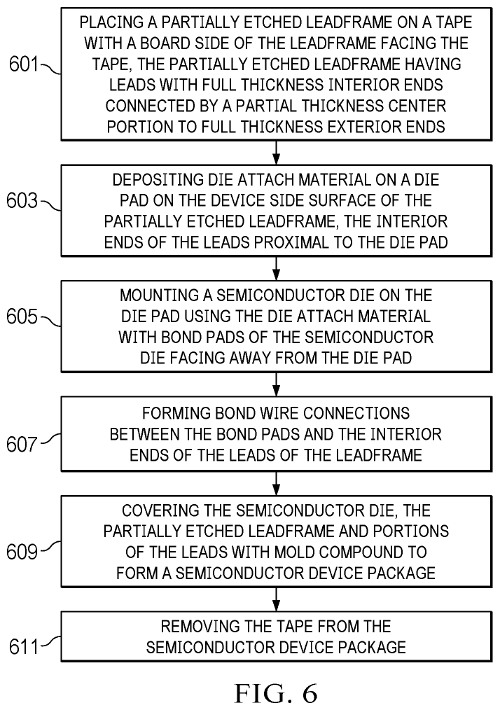

FIG. 6 illustrates, in a flow diagram, steps for forming an arrangement corresponding to the steps shown in the series of illustrations 4A-4E.

At step 601, the method begins by placing a partially etched leadframe on a tape with a board side of the leadframe facing the tape, the partially etched leadframe having leads with full thickness interior ends connected by a partial thickness center portion to full thickness exterior ends (see, for example, the cross section shown in FIG. 4A, with tape 310, leadframe 337, and leads 315). The partially etched leadframe can be manufactured in strips or arrays and mounted on the tape at any time, and step 601 can be performed independently from the other steps.

At step 603, the method continues by depositing die attach material on a die pad on the device side surface of the partially etched leadframe, the interior ends of the leads proximal to the die pad (see FIG. 4B, with the die pad 313 shown, the die attach material 325 is shown deposited on the die pad 313).

At step 605, the method continues by mounting a semiconductor die on the die pad using the attach material with the bond pads of the semiconductor die facing away from the die pad. (See, for example, FIG. 4C, semiconductor die 305 is shown mounted with die attach material 325 to die pad 313, the bond pads 308 face away from the die pad 313).

At step 607, the method continues by forming bond wire connections between the bond pads and the interior ends of the leads of the leadframe. (See FIG. 4D, illustrating leadframe 337 on a heating block 340, and bond wires 319 formed between bond pads 308 and leads 315).

At step 609, the method continues by covering the semiconductor die, the partially etched leadframe and portions of the leads with mold compound to form a semiconductor device package. (See FIG. 4E, mold compound 323 is shown over the semiconductor die 305, the bond wires 319, and portions of the leads 315).

At step 611, the method continues by removing the tape from the semiconductor device package. (See FIG. 3B, for example, with semiconductor package 300 including the semiconductor die 305, the leadframe 337, and the leads 315, and the mold compound 323).

Use of the arrangements provides support of the interior end of leadframe leads during a wire bonding process. The use of the arrangements prevents lead deflection and misalignment observed for wire bonding of when prior methods are used. The arrangements eliminate the defects of packages formed using prior approaches without the need for additional mechanical supports and without requiring added parts to support the leads. The leads used in the leadframes of the arrangements can be efficiently formed during the leadframe manufacturing process using partial etch or stamping operations that are already in use, without added costs. The package layouts, semiconductor die sizes, bond pad layouts, and wire bonding processes are not impacted by the use of the arrangements so the arrangements can be adopted without changes to the semiconductor die design or to the wire bonding tools.

Modifications are possible in the described arrangements, and other alternative arrangements are possible within the scope of the claims.

What is claimed is:

1. An apparatus, comprising:
a metal leadframe comprising:
a die pad in a central portion of the metal leadframe and having a thickness that is the same as a full thickness of the metal leadframe;
leads spaced from the die pad, the leads comprising:
an interior end spaced from the die pad by an opening in the metal leadframe and having the full thickness;
a central portion connected to the interior end and extending away from the die pad having a partial thickness that is less than the full thickness; and
an exterior end having the full thickness extending from the central portion and away from the die pad, the exterior end having a board side surface;
a semiconductor die mounted to the die pad by die attach material and having bond pads on a device side surface facing away from the die pad;
wire bonds coupling bond pads of the semiconductor die to the interior ends of leads of the metal leadframe; and
mold compound covering the semiconductor die, the die pad, the wire bonds, the interior ends of the leads, the central portion of the leads, and portions of the exterior ends of the leads to form a semiconductor device package, and the board side surface of the exterior ends exposed from the mold compound and forming terminals for the semiconductor device package.

2. The apparatus of claim 1, wherein the interior ends of the leads have a board side surface exposed from the mold compound.

3. The apparatus of claim 1, wherein the central portion of the leads have the partial thickness that is one-half the full thickness of the metal leadframe.

4. The apparatus of claim 1, wherein the central portion of the leads have the partial thickness that is less than one-half of the full thickness of the metal leadframe.

5. The apparatus of claim 1, wherein the semiconductor device package is a leaded semiconductor device package and the leads extend beyond the semiconductor device package.

6. The apparatus of claim 1, wherein the die pad has a board side surface exposed from the mold compound.

7. The apparatus of claim 1, wherein the apparatus is a quad flat no-lead (QFN) semiconductor device package.

8. The apparatus of claim 1, wherein the apparatus is a small outline no-lead (SON) semiconductor device package.

9. The apparatus of claim 1, wherein the full thickness of the metal leadframe is between 0.2-0.5 millimeters.

10. The apparatus of claim 1, wherein the central portion of the leads has a curved surface.

11. The apparatus of claim 1, wherein the leads are partially etched or stamped.

12. The apparatus of claim 1, wherein the metal leadframe is a copper leadframe.

13. The apparatus of claim 1, wherein the metal leadframe is a copper leadframe, an Alloy 42 leadframe, a steel leadframe or a stainless steel leadframe.

14. The apparatus of claim 1, wherein the wire bonds are formed from bond wires of gold, aluminum, silver, copper, or palladium coated copper.

15. A method, comprising:
placing a partially etched leadframe on a tape with a board side of the partially etched leadframe facing the tape, the partially etched leadframe having leads with interior ends having a thickness equal to a full thickness of the partially etched leadframe connected by a center portion having a partial thickness less than the full thickness to exterior ends having the full thickness, where the partial thickness is a thickness less than the full thickness;
placing die attach material on a die pad on a device side surface of the partially etched leadframe opposite the board side surface, the interior ends of the leads spaced from the die pad;
placing a semiconductor die on the device side of the die pad using the die attach material with bond pads of the semiconductor die facing away from the die pad;
forming wire bonds between the bond pads and the interior ends of the leads of the partially etched leadframe; and
covering the semiconductor die, the die pad, the wire bonds, the interior ends of the leads, the center portions of the leads, and portions of the exterior ends of the leads with mold compound to form a semiconductor device package.

16. The method of claim 15, wherein forming wire bonds further comprises:
forming a ball at an end of a bond wire protruding from an opening in a capillary of a wire bonder;
using a surface of the capillary, mechanically pressing the ball onto a bond pad to form a ball bond between the bond wire and a bond pad;
moving the capillary, extending the bond wire from the ball bond to a position over an interior end of one of the leads; and
using the capillary, mechanically pressing the bond wire on the interior end of the one of the leads, forming a stitch bond on the interior end of the one of the leads.

17. The method of claim 15, wherein covering the semiconductor die, the die pad, the wire bonds, portions of the interior ends of the leads, the center portions of the leads, and portions of the exterior ends of the leads with mold compound to form a semiconductor device package further comprises exposing a board side surface of the interior ends and a board side surface of the exterior ends from the mold compound.

18. The method of claim 17, and further comprising exposing a board side surface of the die pad from the mold compound.

19. The method of claim 17, wherein the exposed surface of the exterior ends of the leads form terminals for the semiconductor device package that are configured for surface mounting.

20. An apparatus, comprising:
a partially etched copper leadframe having a die pad in a central portion, having a full thickness and a partial thickness that is less than the full thickness, and having leads spaced from the die pad, the leads comprising:
a full thickness interior end spaced from the die pad;
a partial thickness central portion connected to the interior end and extending away from the die pad; and
a full thickness exterior end connected to the central portion and positioned away from the die pad;
die attach material over the die pad;
a semiconductor die mounted to the die pad using the die attach material, the semiconductor die having bond pads on a device side surface facing away from the die pad;
wire bonds coupling the bond pads of the semiconductor die to interior ends of the leads of the partially etched copper leadframe, the wire bonds comprising bond wires of gold, silver, aluminum, copper, or palladium coated copper; and
mold compound covering the semiconductor die, the wire bonds, portions of the interior ends of the leads, and portions of the exterior ends of the leads to form a semiconductor device package, and a board side surface of the exterior ends of the leads exposed from the mold compound to form surface mount terminals of the semiconductor device package.
